(19) United States
(12) Patent Application Publication
(10) Pub. No.: US 2025/0123316 A1
(43) Pub. Date: Apr. 17, 2025

(54) MONITOR STRUCTURES FOR MEASURING DEVICE IMPEDANCE

(71) Applicant: TEXAS INSTRUMENTS INCORPORATED, DALLAS, TX (US)

(72) Inventors: Gang XUE, SAN JOSE, CA (US); Steven BURICH, ALLEN, TX (US)

(21) Appl. No.: 18/487,630

(22) Filed: Oct. 16, 2023

(51) Int. Cl. G01R 31/26; G01R 27/16

(52) U.S. Cl. CPC G01R 31/2607; G01R 27/16

(57) ABSTRACT

In a described example, a semiconductor wafer can include a first monitor structure in a scribe line adjacent to a die, the first monitor structure including a first source region, a first drain region, and a first gate region. The first gate region can include a first elongated finger extending longitudinally between the first source region and the first drain region, as viewed from a top plan view. The semiconductor wafer can include a second monitor structure in the scribe line, the second monitor structure including one or more second source regions, one or more second drain regions, and a plurality of second gate regions. The second gate regions can include a second elongated finger extending longitudinally over a respective region of the die between the one or more second source regions and the one or more second drain regions, as viewed from the top plan view.

### TECHNICAL FIELD

This description relates to systems and methods for impedance measurement, and more particularly, to monitor structures for measuring device impedance.

### BACKGROUND

Die preparation is a part of the semiconductor device fabrication process in which a wafer is prepared for integrated circuit (IC) packaging and testing. The process of die preparation generally includes wafer dicing. Prior to wafer dicing, the wafer is mounted on a tape (e.g., dicing tape). A wafer dicing process is used to separate individual die from a wafer of semiconductor, while mounted to the dicing tape. The dicing process can involve scribing and breaking, mechanical sawing, or laser cutting. Once a wafer has been diced, the die will stay on the dicing tape until the die are extracted by die-handling equipment, such as a die bonder or die sorter, later in the packaging process.

### SUMMARY

In a described example, a semiconductor wafer can include a first monitor structure in a scribe line adjacent to a die, the first monitor structure including a first source region, a first drain region, and a first gate region. The first gate region can include a first elongated finger extending longitudinally between the first source region and the first drain region, as viewed from a top plan view. The semiconductor wafer can include a second monitor structure in the scribe line adjacent to the die, the second monitor structure including one or more second source regions, one or more second drain regions, and a plurality of second gate regions. Each of the second gate regions can include a second elongated finger extending longitudinally over a respective region of the die between the one or more second source regions and the one or more second drain regions, as viewed from the top plan view.

In a described example, a system can include a sensor and a processor. The sensor can be configured to measure a first impedance between first and second terminals of a test device, where the first impedance represents an impedance of a first monitor structure in a scribe line of a semiconductor wafer responsive to applying a first bias voltage across a third terminal and the second terminal of the first monitor structure. The sensor can be configured to measure a second impedance between first and second terminals of the test device, where the second impedance represents an impedance of a second monitor structure in the scribe line of the semiconductor wafer responsive to applying the first bias voltage across a third terminal and the second terminal of the second monitor structure. The sensor can be configured to measure a third impedance between the first and second terminals of the test device, where the third impedance represents an impedance of the first monitor structure responsive to applying a second bias voltage across the third and second terminals of the first monitor structure. The sensor can be configured to measure a fourth impedance between the first and second terminals of the test device, where the fourth impedance represents an impedance of the second monitor structure responsive to applying the second bias voltage across the third and second terminals of the second monitor structure. The processor can be configured to calculate a device impedance based on the first, second, third, and fourth impedance. The device impedance is representative of an impedance of a transistor on a die of a semiconductor wafer adjacent to the scribe line.

In a described example, a method can include measuring a first impedance between first and second terminals of a first monitor structure in a scribe line of a semiconductor wafer responsive to applying a first bias voltage across a third terminal and the second terminal of the first monitor structure, measuring a second impedance between first and second terminals of a second monitor structure in the scribe line of the semiconductor wafer responsive to applying the first bias voltage across a third terminal and the second terminal of the second monitor structure, measuring a third impedance between the first and second terminals of the first monitor structure responsive to applying a second bias voltage across the third and second terminals of the first monitor structure, measuring a fourth impedance between the first and second terminals of the second monitor structure responsive to applying the second bias voltage across the third and second terminals of the second monitor structure, and calculating a device impedance based on the first, second, third, and fourth impedance.

### BRIEF DESCRIPTION OF THE DRAWINGS

FIG. 1 is an illustration of an example semiconductor wafer.

FIG. 2 is a block diagram of an example of a test system for testing a semiconductor wafer.

FIG. 3 is a top plan view illustrating example laterally-diffused metal-oxide semiconductor (LDMOS) transistors.

FIG. 4 is a cross-sectional view illustrating the example LDMOS transistors of FIG. 3.

FIG. 5 is a block diagram of another example of a test system for devices of a semiconductor wafer.

FIG. 6 is a flow diagram illustrating an example method for calculating device impedance.

FIG. 7 is graph illustrating device impedances for different types of monitor structures.

### DETAILED DESCRIPTION

This description relates to systems, methods, and devices to provide for more accurate measurements for device impedance using monitor structures.

For example, a more accurate impedance measurement for a device impedance of the die can be provided by fabricating a first monitor structure and a second monitor structure in a scribe line adjacent to a die. The first and second monitor structures can be transistor structures, such as metal oxide semiconductor field effect transistors (MOSFETs) (e.g., laterally-diffused MOS (LDMOS) transistors). For example, the first and second monitor structures are configured to have the same ON-resistance between respective source and drain regions thereof as the respective transistors on the die. A test system can be configured to measure impedance (e.g., R_{DS} ON) of the first monitor structure at a first bias voltage and measure the R_{DS} of the first monitor structure at a second bias voltage. The test system can also be configured to measure the R_{DS} of the second monitor structure at the first bias voltage and measure the R_{DS} of the second monitor structure at the second bias voltage. Based on the foregoing measurements, metal and/or contact routing related parasitic resistance can be determined and extracted from measurements to provide more accurate impedance measurement for the device impedance.

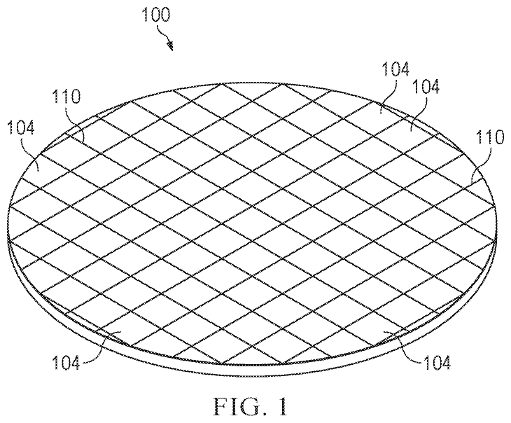

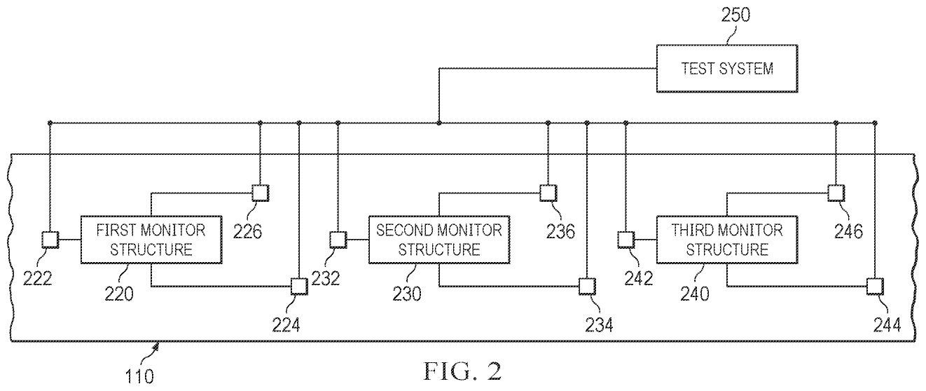

FIG. 1 is an illustration of an example semiconductor wafer 100. As seen in FIG. 1, the semiconductor wafer 100 can include a plurality of die 104, which are separated from each other by scribe lines 110 extending across the semiconductor wafer 100. Generally, a wafer dicing process is used to separate individual die 104 from the semiconductor wafer 100. The dicing process can involve breaking, mechanical sawing, or laser cutting along a scribe line 110. Monitor structures can be fabricated within the scribe line 110, as described herein (see, e.g., FIG. 2). These monitor structures can be utilized during a test phase (e.g., wafer test) to determine a more accurate R_{DS} (e.g., an impedance measurement) by extracting metal and/or contact routing related parasitic resistance from the device impedance.

FIG. 2 is a block diagram of an example of a test system 250 for measuring device impedance for devices of the semiconductor wafer, such as the semiconductor wafer 100 of FIG. 1. In the example of FIG. 2, the test system includes a test fixture (e.g., one or more probes) coupled to respective terminals (e.g., pads) on a surface of a given scribe line 110. As discussed herein, the scribe line 110 on the semiconductor wafer 100 can be fabricated to include different monitor structures, such as a first monitor structure 220, a second monitor structure 230, a third monitor structure 240, etc. As shown in the example of FIG. 2, the different monitor structures (e.g., first monitor structure 220, second monitor structure 230, third monitor structure 240, etc.) can be formed in the scribe line 110 adjacent to a given die. These monitor structures 220, 230, 240 can be instances of respective transistors adjacent the die, and thereby enable a more accurate impedance measurement for device impedance of the die. Each monitor structure 220, 230, 240 includes terminals coupled to respective pads, which are formed of an electrically conductive material (e.g., a metal, such as copper, aluminum, or gold) in the scribe line 110 and configured to be contacted by respective probe tips of the test system 250. For example, pads 222, 224 and 226 are coupled to terminals of the monitor structure 220. The pads 232, 234 and 236 are coupled to terminals of the monitor structure 230, and pads 242, 244 and 246 are coupled to respective terminals of the monitor structure 240.

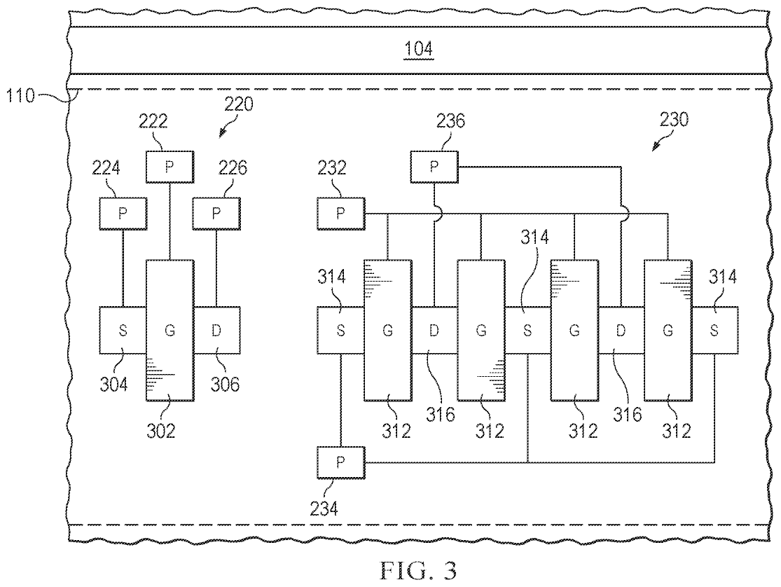

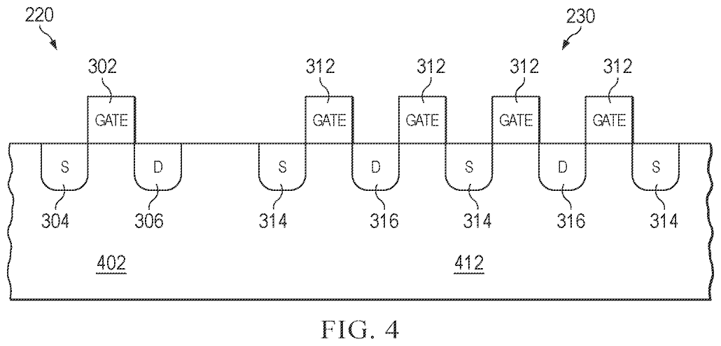

As a further example, FIG. 3 illustrates a top plan view of example monitor structures 220 and 230 which can be fabricated in the scribe line 110 of the semiconductor wafer 100 at locations adjacent to a given die 104, as described herein. FIG. 4 illustrates a cross-sectional view of the example monitor structures 220 and 230 of FIG. 3. In the examples of FIGS. 3 and 4, the monitor structures 220 and 230 are implemented LDMOS transistors. As shown in FIGS. 3-4, the first monitor structure 220 thus can include a first source region 304, a first drain region 306, and a first gate region 302 formed over a substrate 402. The second monitor structure 230 can include one or more second source regions 314, one or more second drain regions 316, and a plurality of second gate regions 312 formed over a substrate 412 (substrate 402 and 412 can be the same substrate in some example scenarios).

In the example of FIGS. 3 and 4, the monitor structure 220 is implemented as a single-finger configuration LDMOS, in which the first gate region 302 can include a first elongated finger (e.g., single-finger configuration) extending longitudinally between the first source region 304 and the first drain region 306, as viewed from a top plan view. The monitor structure 230 is implemented as a multi-finger configuration LDMOS, in which each of the second gate regions 312 can include a respective second elongated finger (e.g., multi-finger configuration). Each second elongated finger 312 extends longitudinally over a respective doped region of the substrate between respective source and drain regions 314 and 316, as viewed from the top plan view of FIG. 3. The multi-finger configuration of the second monitor structure 230 can be more representative of actual MOSFETs on the die because the MOSFETs on the die can have similar multi-finger configurations. The fingers of the single-finger and multi-finger gate regions 302 and 312 can be formed to include polysilicon, for example.

As described herein, each of the monitor structures 220 and 230 can be formed in the scribe line 110 as another instance of a respective transistor formed on the die 104, which can also be an LDMOS transistor. As a result, the first or second monitor structure 220, 230 can be configured to have the same ON-resistance between respective source and drain regions as the respective transistor on the die.

Returning to FIG. 2, it will be appreciated that any number of monitor structures can be included in the scribe line 110 adjacent to one or more dies, and that each of the monitor structures can have the same or different configurations (e.g., single-finger, multi-finger) with respect to other monitor structures in the scribe line 110. As described herein, the first monitor structure 220 has a single-finger configuration and the second monitor structure 230 has a multi-finger configuration. The third monitor structure 240 (when implemented) can have a single-finger configuration, a multi-finger configuration or another configuration according to the on-die transistor for which it provides a corresponding monitor structure. In one example, the third monitor structure 240 can include one or more third source regions, one or more third drain regions, and a plurality of third gate regions, similar to the second monitor structure 230. Each of the third gate regions can thus include a third elongated finger extending longitudinally over a respective region of the die between the one or more third source regions and the one or more third drain regions, as viewed from the top plan view.

According to one example, the device impedance for devices of the semiconductor wafer 100 can be calculated according to the equations below:

$$\frac{{R}_{DS} ( first monitor structure , first voltage )}{{R}_{DS} ( first monitor structure , second voltage )} = \frac{\begin{matrix}{R}_{DS} ( second monitor structure , first voltage ) - \\ {R}_{DS} ( metal parasitic )\end{matrix}}{\begin{matrix}{R}_{DS} ( second monitor structure , second voltage ) - \\ {R}_{DS} ( metal parasitic )\end{matrix}} \qquad ( 1 )$$

$${R}_{DS array} = ( {R}_{DS} ( second monitor structure , first voltage ) - {R}_{DS} ( metal parasitic ) ) * \frac{{width}_{second monitor structure}}{{width}_{first monitor structure}} \qquad ( 2 )$$

The equations above are based on the theory that LDMOS Si R_{DS} is dependent on V_{GS} bias (e.g., gate-to-source bias voltage), while the metal and/or contact routing related parasitic resistance is independent of the V_{GS} bias. Therefore, by measuring a total R_{DS} at more than one V_{GS} bias voltage, the array R_{DS} and R_{DS}(metal parasitic) can be separately extracted and calculated. The test system can thus be configured to calculate the R_{DS}−ON values more accurately.

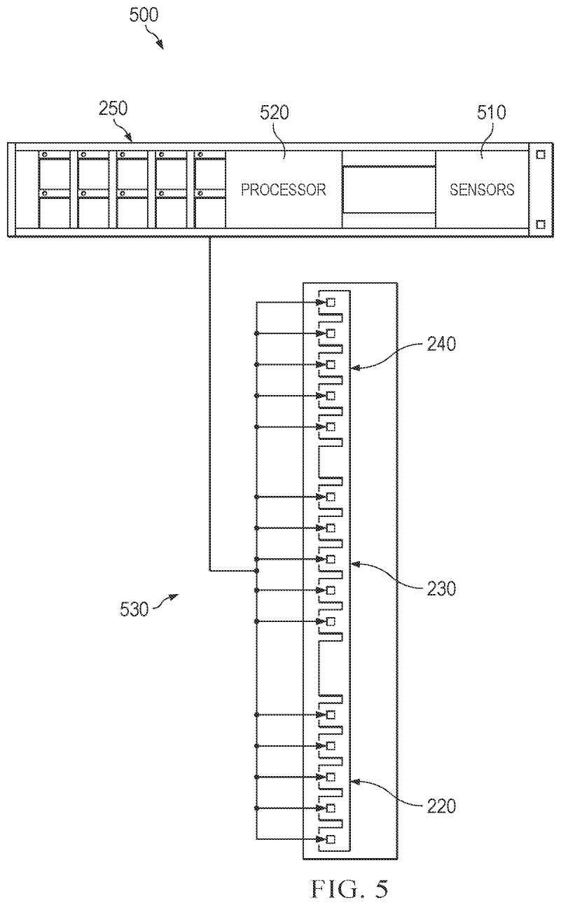

FIG. 5 is a block diagram of another example of a test system 500 for measuring device impedances for respective devices of a semiconductor wafer. The test system can be used to implement the test system of FIG. 2. Accordingly, the description of FIG. 5 can also refer to FIG. 2. The test system 500 can include sensor(s) 510, a processor 520, and a probe card 530. The probe card 530 can be an interface between the test system 500 and a test head, for example. The probe card 530 can include a plurality of probe tips that are configured to electrically contact the pads (e.g., pads 222, 224, 226, 232, 234, 236, 242, 244, 246) of the monitor structures 220, 230, 240. One or more of the probe tips can be configured to apply a bias voltage across two terminals (e.g., across gate and source terminals) of the respective monitor structures 220, 230, 240. The sensor 510 can be configured to measure an impedance across a pair of terminals (e.g., drain and source terminals) of each monitor structure 220, 230, 240 in response to the applied bias voltage. The probe tips of the probe card 530 can be coupled to the sensor 510, which can be configured to measure multiple impedance values at different bias voltages. The processor 520 can be configured to calculate the R_{DS}(metal parasitic) from Equation (1) based on the impedance measurements.

For example, the sensor 510 is configured to measure a first impedance between first and second terminals (e.g., drain and source terminals) of the first monitor structure 220 responsive to applying a first bias voltage across a third terminal and the second terminal (e.g., gate and source terminals) of the first monitor structure 220. The sensor 510 can be configured to measure a second impedance between first and second terminals (e.g., drain and source terminals) of second monitor structure 230 responsive to applying the first bias voltage across a third terminal and the second terminal (e.g., gate and source terminals) of the second monitor structure 230. Additionally, the sensor 510 can be configured to measure a third impedance between the first and second terminals (e.g., drain and source terminals) of the first monitor structure 220 responsive to applying a second bias voltage across the third and second terminals (e.g., gate and source terminals) of the first monitor structure 220. The sensor 510 further can be configured to measure a fourth impedance between the first and second terminals (e.g., drain and source terminals) of the second monitor structure 230 responsive to applying the second bias voltage across the third and second terminals (e.g., gate and source terminals) of the second monitor structure 230. As described herein, the first bias voltage can be different than the second bias voltage. The processor 520 can be configured to calculate a device impedance (e.g., R_{DS}−ON resistance) for one or both monitor structures 220 and 230 based on the first, second, third, and fourth impedance measurements, such as using Equations (1) and (2), for example. Again, the device impedance values can be representative of an impedance of one or more respective transistors on the die 104 of the semiconductor wafer 100 adjacent to the scribe line 110.

The first, second, third, and fourth impedance can be measured from the first monitor structure 220, the second monitor structure 230, the third monitor structure 240, etc. in the scribe line 110. The processor 520 can be configured to calculate a parasitic impedance (e.g., R_{DS}(metal parasitic)) of the first, second, and third monitor structures 220, 230, 240 based on the first, second, third, and fourth impedance. The processor 520 can be configured to determine the device impedance (e.g., R_{DS array}) based on the parasitic impedance determined for each of the first, second, third monitor structures 220, 230, 240 (e.g., using Equation 2).

Additionally, the processor 520 can be configured to assign a score to the die 104 based on the device impedance. For example, die having a device impedance below a first threshold can be assigned a first score and die having a device impedance below a second threshold can be assigned a second score. Lower R_{DS} values may be scored higher, for example. Thus, devices or die with device impedances associated with higher or more favorable performance can be assigned different scores then die with device impedances associated with less favorable performance. The processor 520 can be configured to separate the die 104 from the semiconductor wafer 100 based on the device impedance. For example, after the die 104 are sliced, the die 104 associated with the device impedance below the first threshold can be separated from die associated with the device impedance below the second threshold. The processor 520 can be configured to bin the die 104 based on the assigned score. In this way, the processor 520 can bin out high-performance die from lower performing die.

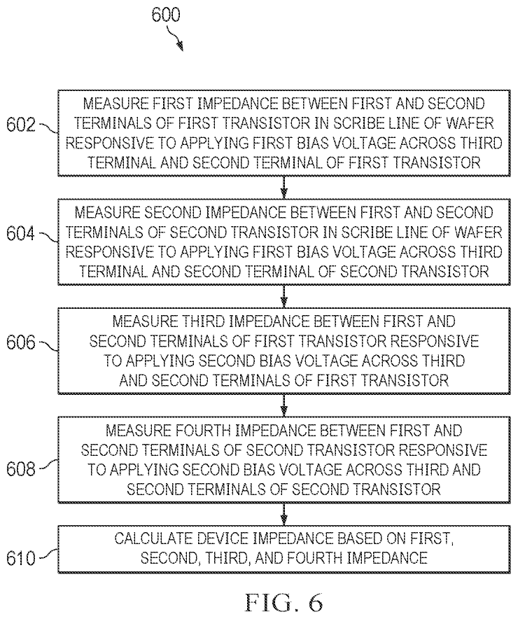

FIG. 6 is a flow diagram illustrating an example method 600 for calculating device impedance. The method can be used by the test systems (e.g., FIGS. 2 and/or 5) to determine impedance. Accordingly, the description of FIG. 6 also refers to FIGS. 1-5. In the described example, the method 600 can include measuring 602 a first impedance between first and second terminals of a first monitor structure in a scribe line of a semiconductor wafer responsive to applying a first bias voltage across a third terminal and the second terminal of the first monitor structure. For example, the measurement at 602 can be implemented by the sensors 510 of the probe card 530. The method 600 can include measuring 604 a second impedance between first and second terminals of a second monitor structure in the scribe line of the semiconductor wafer responsive to applying the first bias voltage across a third terminal and the second terminal of the second monitor structure. For example, the measurement at 604 can be implemented by the sensors 510 of the probe card 530. The method 600 can include measuring 606 a third impedance between the first and second terminals of the first monitor structure responsive to applying a second bias voltage across the third and second terminals of the first monitor structure. For example, the measurement at 606 can be implemented by the sensors 510 of the probe card 530. The method 600 can include measuring 608 a fourth impedance between the first and second terminals of the second monitor structure responsive to applying the second bias voltage across the third and second terminals of the second monitor structure. For example, the measurement at 608 can be implemented by the sensors 510 of the probe card 530. The method 600 can include calculating 610 a device impedance based on the first, second, third, and fourth impedance. For example, the calculation at 610 can be implemented by the processor 520.

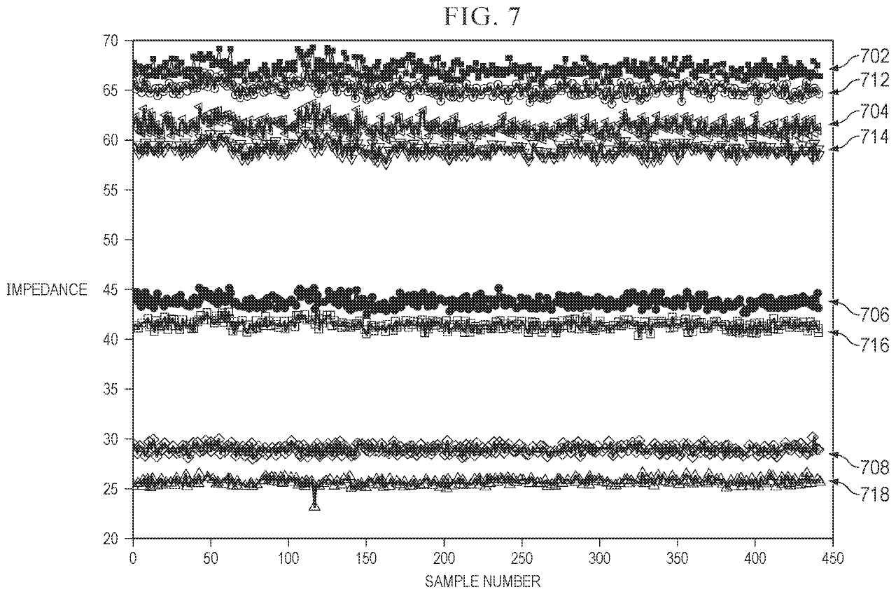

FIG. 7 is an illustration of device impedances (e.g., y-axis) for different types of monitor structures across an example lot of sample devices (e.g., x-axis). For example, four different voltage rating sets of devices are shown with each set tested under the first testing scenario 702, 704, 706, 708 where only the single-finger type monitor structures are utilized to calculate the device impedance and the second testing scenario where both the single-finger and multi-finger type monitor structures are utilized to calculate the device impedance. As seen in FIG. 7, the second testing scenario 712, 714, 716, 718 for the four different voltage rating sets of devices where both the single-finger and multi-finger type monitor structures are utilized in the impedance calculation results in lower device impedances once the metal and/or contact routing related parasitic resistances are extracted from the overall device impedance compared to the first testing scenario 702, 704, 706, 708 where only the single-finger type monitor structures are utilized, thereby providing a more accurate impedance measurement for device impedance of the die. In other words, the device impedance of a first voltage rating device is artificially higher when measured using the first testing scenario 702 than when measured using the second testing scenario 712, the device impedance of a second voltage rating device is artificially higher when measured using the first testing scenario 704 than when measured using the second testing scenario 714, the device impedance of a third voltage rating device is artificially higher when measured using the first testing scenario 706 than when measured using the second testing scenario 716, and the device impedance of a fourth voltage rating device is artificially higher when measured using the first testing scenario 708 than when measured using the second testing scenario 718.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In this description, a device that is “configured to” perform a task or function can be configured (e.g., programmed and/or hardwired) at a time of manufacturing by a manufacturer to perform the function and/or can be configurable (or reconfigurable) by a user after manufacturing to perform the function and/or other additional or alternative functions. The configuring can be through firmware and/or software programming of the device, through a construction and/or layout of hardware components and interconnections of the device, or a combination thereof. Furthermore, a circuit or device that is described herein as including certain components can instead be configured to couple to those components to form the described circuitry or device. For example, a structure described herein as including one or more semiconductor elements (such as transistors), one or more passive elements (such as resistors, capacitors, and/or inductors), and/or one or more sources (such as voltage and/or current sources) can instead include only the semiconductor elements within a single physical device (e.g., a semiconductor die and/or integrated circuit (IC) package) and can be configured to couple to at least some of the passive elements and/or the sources to form the described structure, either at a time of manufacture or after a time of manufacture, such as by an end-user and/or a third-party.

The phrase “based on” means “based at least in part on”. Therefore, if X is based on Y, X may be a function of Y and any number of other factors.

Modifications are possible in the described embodiments, and other embodiments are possible, within the scope of the claims.

What is claimed is:

1. A semiconductor wafer, comprising:
a first monitor structure in a scribe line adjacent to a die and including a first source region, a first drain region, and a first gate region, wherein the first gate region comprises a first elongated finger extending longitudinally between the first source region and the first drain region, as viewed from a top plan view; and
a second monitor structure in the scribe line adjacent to the die and including one or more second source regions, one or more second drain regions, and a plurality of second gate regions, wherein each of the second gate regions comprises a second elongated finger extending longitudinally over a respective region of the die between the one or more second source regions and the one or more second drain regions, as viewed from the top plan view.

2. The semiconductor wafer of claim 1, comprising:
a third monitor structure in the scribe line adjacent to the die and including one or more third source regions, one or more third drain regions, and a plurality of third gate regions, wherein each of the third gate regions comprises a third elongated finger extending longitudinally over a respective region of the die between the one or more third source regions and the one or more third drain regions, as viewed from the top plan view.

3. The semiconductor wafer of claim 1, wherein the second monitor structure is configured to represent a respective transistor on the die.

4. The semiconductor wafer of claim 3, wherein the respective transistor on the die of the semiconductor wafer is a laterally-diffused metal-oxide semiconductor (LDMOS).

5. The semiconductor wafer of claim 3, wherein the first or second monitor structure is configured to have the same ON-resistance between respective source and drain regions as the respective transistor on the die.

6. The semiconductor wafer of claim 1, comprising an arrangement of electrically conductive pads and traces in the scribe line and exposed on a surface of the semiconductor wafer, wherein the pads are coupled to respective gate, source, and drain regions.

7. A system, comprising:
a sensor configured to measure:
a first impedance between first and second terminals of a test device, wherein the first impedance represents an impedance of a first monitor structure in a scribe line of a semiconductor wafer responsive to applying a first bias voltage across a third terminal and the second terminal of the first monitor structure;
a second impedance between first and second terminals of the test device, wherein the second impedance represents an impedance of a second monitor structure in the scribe line of the semiconductor wafer responsive to applying the first bias voltage across a third terminal and the second terminal of the second monitor structure;
a third impedance between the first and second terminals of the test device, wherein the third impedance represents an impedance of the first monitor structure responsive to applying a second bias voltage across the third and second terminals of the first monitor structure;
a fourth impedance between the first and second terminals of the test device, wherein the fourth impedance represents an impedance of the second monitor structure responsive to applying the second bias voltage across the third and second terminals of the second monitor structure; and
a processor configured to calculate a device impedance based on the first, second, third, and fourth impedance, wherein the device impedance is representative of an impedance of a transistor on a die of a semiconductor wafer adjacent to the scribe line.

8. The system of claim 7, wherein the transistor on the die is a laterally-diffused metal-oxide semiconductor (LDMOS) transistor and the device impedance is representative of an ON-resistance of the LDMOS transistor.

9. The system of claim 7, wherein the processor is configured to calculate a parasitic impedance of the first or second monitor structure based on the first, second, third, and fourth impedance, and wherein the device impedance is determined based on the parasitic impedance of the first or second monitor structure.

10. The system of claim 7, wherein the processor is configured to assign a score to the die based on the device impedance.

11. The system of claim 7, wherein the first, second, third, and fourth impedance are measured from a first and second monitor structure in the scribe line adjacent to the die, and wherein the first and second monitor structures each include electrically conductive pads and traces.

12. The system of claim 11, wherein the first monitor structure includes a first source region, a first drain region, and a first gate region, wherein the first gate region comprises a first elongated finger extending longitudinally between the first source region and the first drain region, as viewed from a top plan view.

13. The system of claim 12, wherein the second monitor structure includes one or more second source regions, one or more second drain regions, and a plurality of second gate regions, wherein each of the second gate regions comprises a second elongated finger extending longitudinally over a respective region of the die between the one or more second source regions and the one or more second drain regions, as viewed from the top plan view.

14. The system of claim 13, wherein:
the first, second, third, and fourth impedance are measured from the first, second, and a third monitor structure in the scribe line adjacent to the die, and
the third monitor structure includes one or more third source regions, one or more third drain regions, and a plurality of third gate regions, wherein each of the third gate regions comprises a third elongated finger extending longitudinally over a respective region of the die between the one or more third source regions and the one or more third drain regions, as viewed from the top plan view.

15. A method, comprising:
measuring a first impedance between first and second terminals of a first monitor structure in a scribe line of a semiconductor wafer responsive to applying a first bias voltage across a third terminal and the second terminal of the first monitor structure;
measuring a second impedance between first and second terminals of a second monitor structure in the scribe line of the semiconductor wafer responsive to applying the first bias voltage across a third terminal and the second terminal of the second monitor structure;
measuring a third impedance between the first and second terminals of the first monitor structure responsive to applying a second bias voltage across the third and second terminals of the first monitor structure;
measuring a fourth impedance between the first and second terminals of the second monitor structure responsive to applying the second bias voltage across the third and second terminals of the second monitor structure; and
calculating a device impedance based on the first, second, third, and fourth impedance.

16. The method of claim 15, wherein the device impedance is representative of an impedance of a transistor on a die of the semiconductor wafer adjacent to the scribe line.

17. The method of claim 16, wherein the transistor on the die is a laterally-diffused metal-oxide semiconductor (LDMOS) and the device impedance is representative of an ON-resistance of the LDMOS transistor.

18. The method of claim 16, comprising:
assigning a score to the die based on the device impedance;
separating the die from the semiconductor wafer; and
binning the die based on the score.

19. The method of claim 15, comprising calculating a parasitic impedance of the first monitor structure or the second monitor structure based on the first, second, third, and fourth impedance, wherein the device impedance is determined based on the parasitic impedance of the first or second monitor structure.

20. The method of claim 15, wherein the first bias voltage is different than the second bias voltage.
